(19) United States
(12) Patent Application Publication
(10) Pub. No.: US 2007/0169962 A1
(43) Pub. Date: Jul. 26, 2007

(54) LED base structure

(75) Inventors: Tu-Hsien Liang, Banciao City (TW); Yi-Wen Hsu, Banciao City (TW)

Correspondence Address: Troxell Law Office Pllc, Suite 1404, 5205 Leesburg Pike, Falls Church, VA, 22041, US

(73) Assignee: Bao Ping International Co., Ltd.

(21) Appl. No.: 11/335,547

(22) Filed: Jan. 20, 2006

(51) Int. Cl. H01L 23/48

(52) U.S. Cl. 174/527

(57) ABSTRACT

An LED (Light Emitting Diode) base structure is constituted by a seat, buttons, and conduction pieces, wherein an emplacement sink of the seat is installed with the plurality of conduction pieces to facilitate an achievement of a control of multi-point conduction for a connection device through the installation of plurality of conduction pieces, upon connecting the base with the connection device.

### BACKGROUND OF THE INVENTION

(a) Field of the Invention

The present invention relates to an LED (Light Emitting Diode) base structure, and more particularly to an improved structure of a base of an LED.

(b) Description of the Prior Art

An ordinary light emitting diode is fixed on a circuit board by welding, which will require a working time for installing, and will not be easy during implementation.

Referring to FIG. 1 and FIG. 2, it shows another conventional way wherein a base A is assembled and then connected to a circuit board for fixing. However, there are only two conduction pieces A3 in an emplacement sink A2 of a seat A1 of the base A for providing a conduction of an anode and a cathode of external power source, which enables the base A to only perform a single-point control.

Accordingly, how to solve the aforementioned problems is a technical issue to be resolved by the inventor of present invention.

### SUMMARY OF THE INVENTION

The present invention is to provide an improved LED (Light Emitting Diode) base structure, wherein an improvement is made to conduction pieces and a seat of the base, such that a control of multi-point conduction can be achieved through an installation of the plurality of conduction pieces, upon assembling a connection device with the base.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of a conventional application.

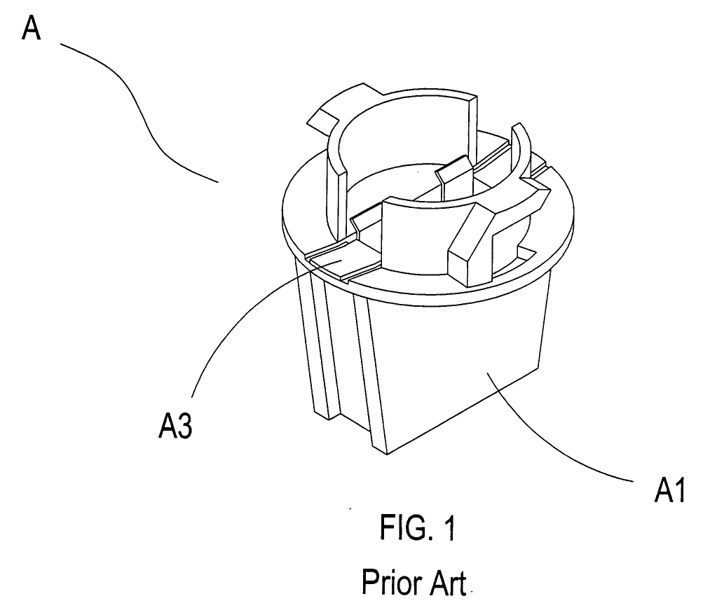

FIG. 2 shows an exploded view of a conventional application.

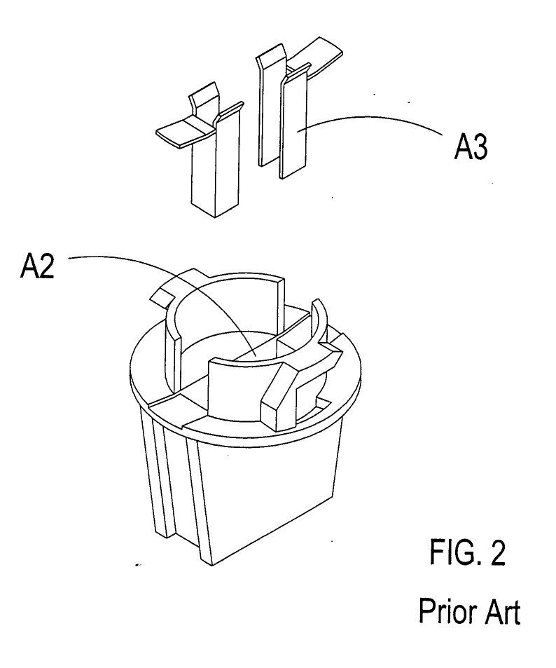

FIG. 3 shows a perspective view of the present invention.

FIG. 4 shows an exploded view of the present invention.

FIG. 5 shows a schematic view of an embodient of the present invention.

FIG. 6 shows a second schematic view of an embodient of the present invention.

FIG. 7 shows a third schematic view of an embodient of the present invention.

FIG. 8 shows a schematic view of a further embodient of the present invention.

### DETAILED DESCRIPTION OF THE PREFERRED EMBODIMENTS

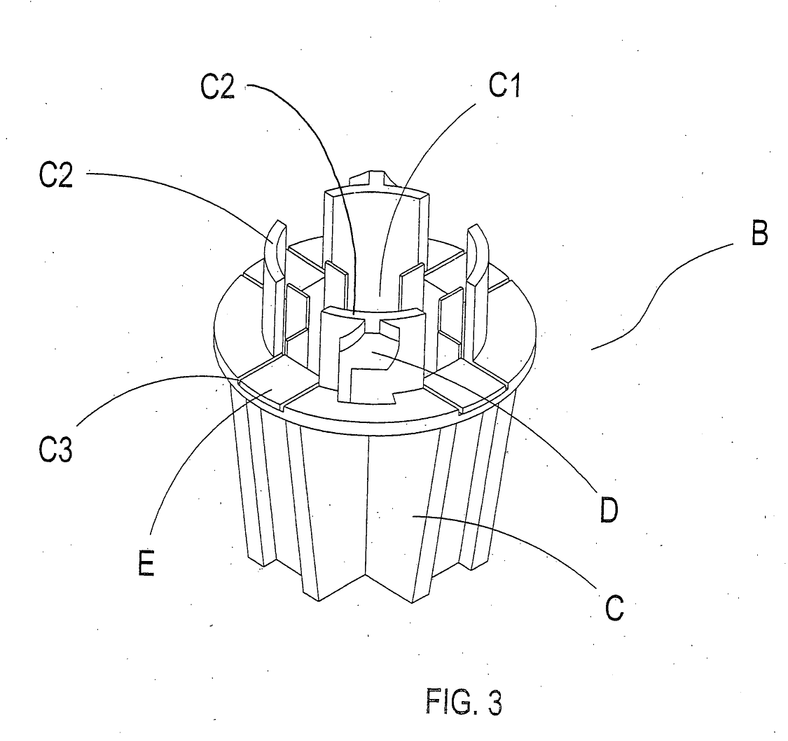

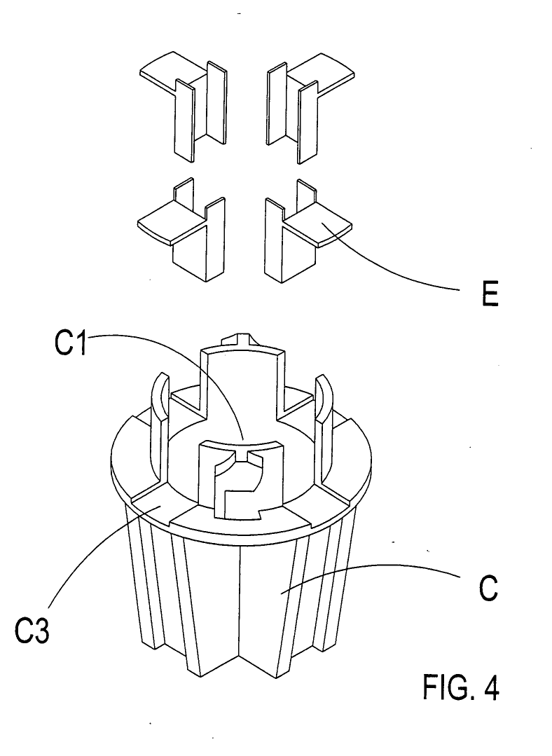

Referring to FIG. 3 and FIG. 4, a base B is composed of a seat C, buttons C, and conduction pieces E, wherein an emplacement sink C1 is installed in an interior at one side of the seat C, a plurality of press pieces C2 is located on the emplacement sink C1, the buttons D are located on the press pieces C2 which are separated with each other by a gap C3, and the conduction pieces E are installed in the gap C3 and are extended into the emplacement sink C1.

To facilitate an implementation and to perform a multi-point control, the base B is provided with the plurality of conduction pieces E for performing the multi-point control upon inserting an external connection device into the emplacement sink C1, and for enabling the connection device to be tightly assembled with the base B through a clipping of the plurality of press pieces C2. In addition, the buttons D are used for latching and fixing upon assembling the base B with a circuit board; therefore, an extra welding action is not needed, thereby facilitating the assembling and dismantling of replacement.

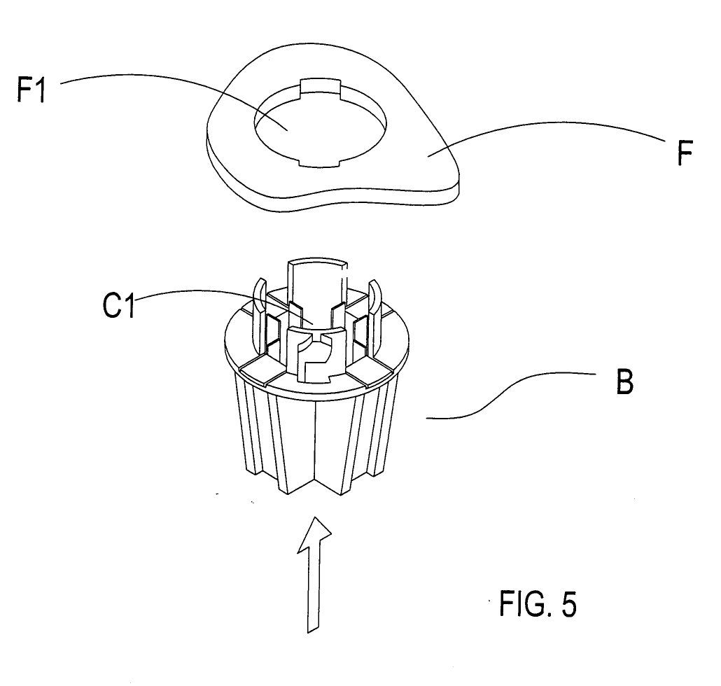

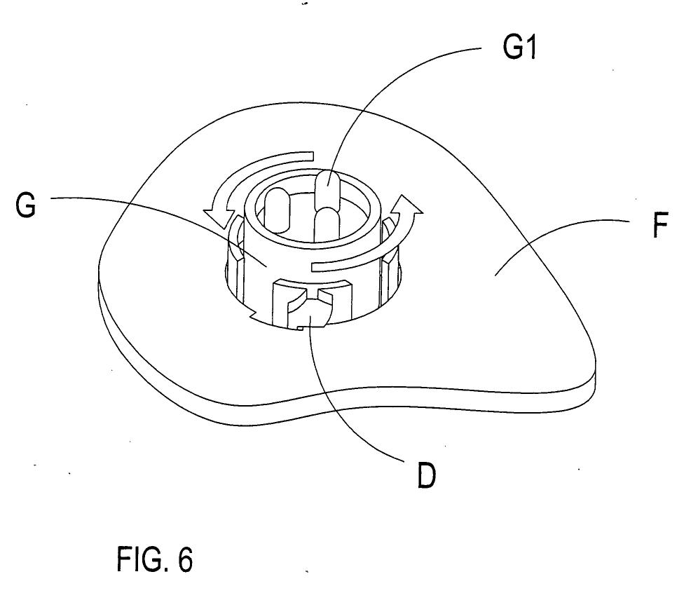

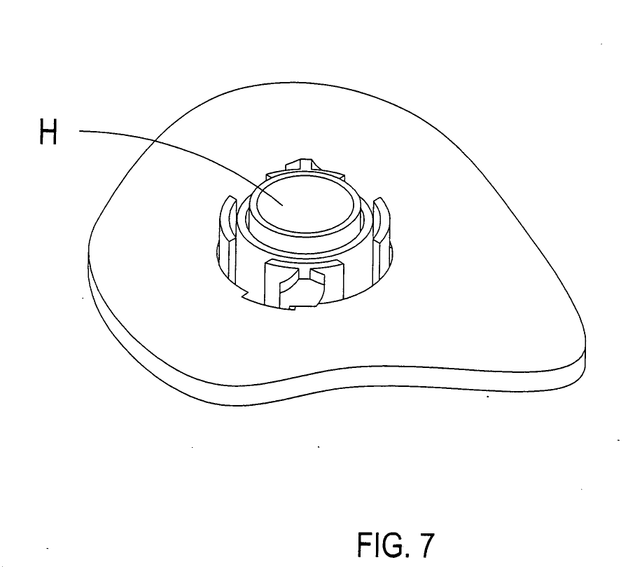

Referring to FIG. 5, FIG. 6, and FIG. 7, when the base B is connected with an assembly hole F1 on a circuit board F, the base B is rotated to enable the buttons D to be latched into the assembly hole F1 of the circuit board F, without requiring the extra welding, so as to facilitate dismantlement.

A lamp holder G of LED (Light Emitting Diode) is assembled in the emplacement sink C1 of the base B, so as to enable a light emitting diode G1 to be working normally on the circuit board F. A multiplex switch H can be further assembled with the emplacement sink C1 of the base B, such that the multiplex switch H can be optionally switched on the circuit board F.

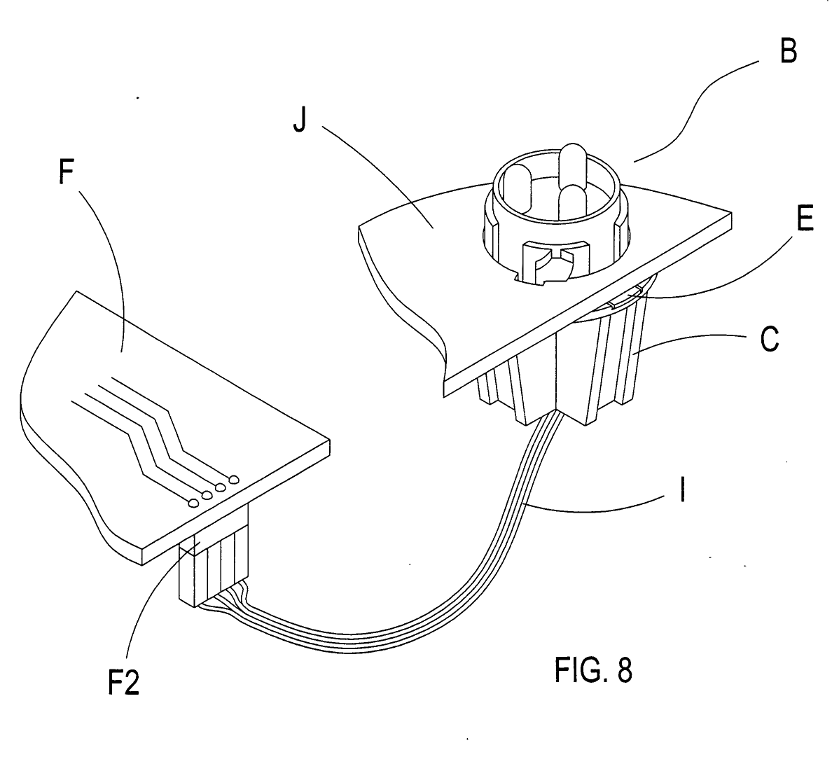

In addition, referring to FIG. 8, the base B is further provided with a plurality of conduction wires I which is installed on the seat C and is electrically connected with the plurality of conduction pieces E. Therefore, the base B can be directly installed on a fixing board J, and a control of multi-point conduction can be performed through a connection of the conduction wires I to a terminal seat F2 on the circuit board F.

To further manifest the advancement and practicability of the present invention, the present invention is compared with a conventional application as below:

Shortcomings of a Conventional Application
1. It contains only two conduction pieces, which can only perform a control of single-point conduction.
2. It is provided with a low compatibility.

Advantages of the Present Invention
1. It is provided with a plurality of conduction pieces, therefore a control of multi-point conduction can be performed.
2. It is provided with a high compatibility with an associated device.
3. It is provided with a broader range of application.
4. It is provided with advancement and practicability.
5. It is provided with an industrial competitiveness.

It is of course to be understood that the embodiments described herein is merely illustrative of the principles of the invention and that a wide variety of modifications thereto may be effected by persons skilled in the art without departing from the spirit and scope of the invention as set forth in the following claims.

1. (canceled)

2. The LED base structure according to claim 5, wherein the buttons are used for latching and fixing upon assembling the base on a circuit board, so as to facilitate dismantlement without requiring an extra welding.

3. The LED base structure according to claim 5, wherein the connection device is a lamp holder of LED or a switch seat having a multi-stage control.

4. The LED base structure according to claim 5, further comprising a plurality of conduction wires electrically connected with the plurality of conduction pieces, the plurality of conduction wires controlling multi-point conduction.

5. An LED base structure comprising:
a seat;
an emplacement sink installed in an interior of the seat;
a plurality of press pieces surrounding the emplacement sink, at least two of the press pieces having buttons thereon, the plurality of press pieces being separated from each other by a plurality of gaps; and
a plurality of conduction pieces extending through the interior of the emplacement sink with one of the plurality of conduction pieces being located in each of the gaps, each of the plurality of conduction pieces extending into each of the gaps, wherein the plurality of conduction pieces are configured for multi-point conduction when a connection device is installed in the emplacement sink.
